(19) United States
(12) Patent Application Publication
(10) Pub. No.: US 2025/0323116 A1
(43) Pub. Date: Oct. 16, 2025

(54) SEMICONDUCTOR DEVICE AND METHOD FOR MANUFACTURING THE SAME

(71) Applicant: Infineon Technologies Austria AG, Villach (AT)

(72) Inventor: Wolfgang Scholz, Olching (DE)

(21) Appl. No.: 19/174,236

(22) Filed: Apr. 9, 2025

(30) Foreign Application Priority Data
Apr. 15, 2024 (DE) 102024203459.2

(51) Int. Cl. H01L 23/367; H01L 23/495

(52) U.S. Cl. CPC H01L 23/3677; H01L 23/49568

(57) ABSTRACT

A semiconductor device includes: a substrate; a die having a first and a second surface, the die being embedded in the substrate; a first heatsink arranged at a first surface of the substrate; and a second heatsink arranged at a second surface of the substrate. The substrate includes a thermally conductive structure arranged between the first surface of the die and the first heatsink, and a thermally isolating structure arranged between the second surface of the die and the second surface of the substrate opposite the first surface.

### TECHNICAL FIELD

The present disclosure relates to a semiconductor device and a method for manufacturing a semiconductor device comprising an embedded component for high voltage applications.

### BACKGROUND

High voltage applications require smaller formfactors due to emerging problems with stray inductances within single packages. Therefore, it is desirable to embed semiconductor dies into a wired substrate to reduce parasitic inductances by reducing the free length of connectors and inter-die interconnects. However, an embedded die operating at high voltages and high switching speeds will be a significant heat source. In order not to compromise proper operation of the die, the substrate and possible surface mounted devices (SMDs) in the vicinity of the die, heat energy emerging from the die needs to be dissipated and lead away from the heat source. A common approach to dissipate heat from a die is to attach a heatsink to one side of the substrate. As heat produced by the die is however lead into all spatial directions, there may be areas on the substrate which may become hot, and which may hence not be suitable for mounting SMDs or may even not be usable at all. Therefore, it is an object of the invention to provide a semiconductor device having enhanced heat transfer characteristics.

### SUMMARY

According to a first aspect, a semiconductor device is provided, the semiconductor device comprising a substrate, a die having a first and a second surface, wherein the die is embedded in the substrate, a first heatsink arranged at a first surface of the substrate, and a second heatsink arranged at a second surface of the substrate, wherein the substrate comprises a thermally conductive structure, arranged between the first surface of the die and the first heatsink; and a thermally isolating structure arranged between the second surface of the die and the second surface of the substrate opposite the first surface.

According to the first aspect, the die is embedded in the substrate to reduce parasitic inductances by reducing the free path of interconnects. The substrate may be a multilayer substrate comprising several metal and non-metal layers and an epoxy-carrier. Materials of the substrate may be Epoxy, Imide, Bismaleimidetriazine and Benzoxazine, to enable multilayer-embedding. Further, the substrate may be a Printed Circuit Board (PCB), consisting of stacked layers of metal embedded in an epoxy matrix. The PCB will be described in detail below.

The layers in the substrate may be generally symmetrical, i.e. may be arranged equally distributed with respect to a centerline of the substrate to reduce warpage of the substrate. The substrate may have a first (lower) surface and a second (upper) surface. A first heatsink may be attached to the first surface of the substrate. A heat sink is a spatially limited area or body that releases the thermal energy stored or supplied in it to an adjacent medium. Adjacent media can be solid objects, liquids, or gases.

The die may comprise a first side comprising drain and collector connections. Further, the die may comprise a second (upper) side, the second upper side being a control side and comprising gate and emitter connections.

The die may be completely buried and surrounded by the substrate but may also be just partly embedded. Embedded does not necessarily mean that the die is arranged in a recess of the substrate, but the die could also be mounted on the substrate and be surrounded by the substrate. As the die will be a source of thermal energy, which will dissipate in all spatial directions into the surrounding substrate, the substrate will get hot during operation. Particularly, at high voltage applications (generally at voltages above 200V), the substrate and associated areas will be subject to thermal stress. To keep the temperature of the die below a certain threshold, it is required to lead heat away from the die and to dissipate the energy. Therefore, the substrate comprises the thermally conductive structure, which is configured to lead heat away from the lower side of the die towards the first heatsink at the first (lower) side of the substrate. As the first heatsink is arranged at the first surface of the substrate, the first surface may not be usable to attach further devices onto the first surface of the substrate within a footprint of the first heatsink.

As heat dissipates in all spatial directions, heat will also be lead away from the upper, second side of the die towards the second surface of the substrate. The second surface of the substrate will therefore become hot as well. Hence, usability of the upper surface of the substrate to attach sensitive SMDs is possibly diminished. To reduce heat transfer from the upper side of the die to the second (upper) side of the substrate, the substrate comprises the thermally isolating structure. The thermally isolating structure isolates the second side of the substrate form the heat source, the die. The thermally isolating structure is therefore arranged between the upper surface of the substrate and the heat source, i.e. the second, upper surface of the die. Thereby, a heat flux to the upper side of the substrate is reduced. Consequently, temperatures on the upper surface of the substrate can be reduced and a surface area of the substrate overhead the heat source may be better usable for attaching SMDs. Thus, it may be possible to attach SMDs in an area overhead the die and/or closer to the footprint of the die or even in an area of the second surface of the substrate which lies within a footprint of the die.

Further, as the thermally isolating structure has a thermal conduction coefficient which is greater than zero, heat transfer through the thermally insulating structure will occur over time and the upper surface of the substrate will heat up as long as the heat source is in operation. To further reduce an amount of heat which is transferred through the thermally isolating structure to the upper surface of the substrate, the second heatsink is attached to the upper surface of the substrate. The second heatsink leads the transferred heat energy from the upper side of the substrate into a cooling medium. Both the cooling media of the first and the second heatsink may be the surrounding air, but both heatsinks may also comprise or operate with any other cooling liquid or gas. By virtue of the second heatsink, the surface temperature of the upper side of the substrate is further reduced. As a result, an area on the upper surface of the substrate in which sensitive SMDs may be attached, is enlarged.

A thermal conduction coefficient of the thermally isolating structure is in the range of 0.3 W/mK, preferably below, wherein the thermally conductive structure has a thermal conduction coefficient in a range of 3-10 W/mK, i.e. at least ten times higher than the isolating structure. The thermally isolating structure may be a reduced thermal conductivity epoxy, wherein the thermally conductive structure may be an enhanced thermal conductivity epoxy. Both the thermally conductive structure and the thermally isolation structure may consist of one or more layers or may be single layers. Further, the thermally isolating structure may be embedded in the substrate and arranged between a metallization layer forming the upper surface or cover layer of the substrate and a wiring layer, wherein the wiring layer may be arranged as to contact the upper side of the die, by way of wires, vias or the like. The wiring layer may be electrically connected to the metallization layer, forming a DC link.

In an embodiment a footprint of the first heatsink overlaps a footprint of the die. “Footprint” generally describes the area or space that an object or system occupies or requires in a specific application or environment. In the present context, the term “footprint” refers to the size of an electronic component, particularly the total area that the component occupies on a PCB. A smaller footprint of a component can help achieve a higher density of components on the PCB. The footprint of the first heat spreader is larger than the footprint of the die and the footprint of the die is included in the footprint of the first heat spreader, from a topside view. Heat being lead away from the first surface of the die, by the thermally conductive structure, will spread in a circular spatial manner from the heat source. Hence, to enable the first heat spreader to collect most of the transferred heat, the footprint of the first heat spreader is larger than the footprint of the die. This enables higher efficiency of the first heat spreader by having short and direct ways for heat transfer from the die to the first heatsink.

In a further embodiment a footprint of the second heatsink overlaps a footprint of the die and/or the second heatsink is a device mounted on the second surface of the substrate (SMD). To implement short ways for heat transfer, the second heatsink also at least partly overlaps the footprint of the die from a topside view. Particularly, a non-temperature sensitive SMD could act as a heat spreader, too, since any device attached to the upper surface of the substrate will enlarge a surface which can be used to transfer heat from the surface to a cooling medium, e.g. the surrounding air. If a non-temperature-sensitive is used as a heat spreader, it may be possible to mount the non-temperature SMD directly overhead the die, i.e. a footprint of the die would be included in a footprint of the second heatsink. The thermally isolating structure may be a continuous structure above the die, i.e. may be free of any through connections. Electrical through-connections, connecting e.g. the wiring layer contacting the die and the metallization layer on the surface of the substrate, are preferably arranged outside the footprint of the die and outside the footprint of the second heatsink, in order not to enable heat flux to the upper surface of the substrate.

In a further embodiment the substrate comprises a leadframe, wherein the leadframe comprises a heat spreading portion configured to contact the first side of the die, the heat spreading portion comprising a via structure to contact a metal layer arranged between the heat spreading portion and the first side of the substrate, wherein the metal layer is part of the thermally conductive structure.

The substrate may comprise a leadframe, e.g. a metal structure on which the die or other electronic components are mounted. The leadframe provides electrical connections between the die and the outside world by way of small wires, typically made of gold or copper, that connect the chip to the leads of the leadframe. In the present embodiment, the leadframe serves as a carrier for the die. The die may be fixedly attached to the leadframe. The leadframe may comprise a heat spreading portion, which acts as a heat spreader, which leads and distributes heat away from the die. The die may be attached to the heat spreading portion. Particularly, the heat spreading portion may be a pillow-shaped integral part of the leadframe and may contact the first (lower) side of the die. The heat spreading portion may be a copper pillow.

The leadframe also provides physical support for the die and protects it from damage. It may be made of a material such as copper, copper alloy, or iron-nickel alloy, and is designed to be compatible with the manufacturing processes used to create the die. The heat spreading portion is configured to dissipate heat away from a heat-generating device, such as the die.

In the case of a HV semiconductor die, the heat spreader may also be a metal plate that is attached to the die, usually with a layer of thermal paste in between. The heat spreader helps to spread the heat generated by the die over a larger surface area, making it easier for a cooling device such as the first heat sink to dissipate the heat.

The heat spreaders may be made from a variety of materials, including copper, aluminum, or a combination of both. The heat spreading portion may comprise a via structure to contact a further metal layer, which is arranged between the first heat sink and the heat spreading portion. The via structure may be a thermally conductive metal structure and may act as a path for enhanced heat flux from the heat spreader into the thermally conductive structure and hence to the first heatsink.

The metal layer may be part of the thermally conductive structure. By virtue of the heat spreader, thermal energy is better dissipated and spread over a larger area to be better distributed and can thus be better received by the first heatsink. Overall heat dissipation and cooling of the die is therefore enhanced.

In a further embodiment, the isolating structure has a heat transfer coefficient below 0.3 W/mK. As heat transfer and hence a surface temperature to the upper side of the substrate are subject to the heat transfer capability of the isolating structure, i.e. the quality of isolation, a low heat transfer coefficient of the thermally isolating structure is desired. Particularly, if the heat transfer coefficient is below 0.3 W/Km, a surface temperature of the upper surface of the substrate will be low enough to prevent damage to sensitive SMDs in the vicinity of the footprint of the die or to non-sensitive SMDs directly overhead the die.

Particularly, the isolating structure is one of a honeycomb structure, a brick structure, a gas filled honeycomb structure, a structure comprising gas-filled cavities. Gas-filled structures have particularly low heat transfer coefficients. A honeycomb structure is a type of cellular or matrix structure that is composed of hexagonal cells or cavities arranged in a regular pattern. The resulting structure is lightweight, yet strong and rigid, making it ideal for use in a variety of applications where strength and weight are important factors. If the cavities of the honeycomb structure are filled with gas, the structure wis also a very good isolator.

As the hexagonal shape of the cells in a honeycomb structure provides a high strength-to-weight ratio, as the structure is able to distribute stress and strain evenly across the entire surface. Under thermal stress, like in the present case, the gas filled honeycomb structure may be a good trade-off between isolation and mechanical resistance.

The same applies to a structure comprising arbitrary gas filled cavities, which contribute to good isolation properties. The structure may be a continuous structure which is free of any thermally conductive through connections.

According to a second aspect of the present disclosure a method for manufacturing a semiconductor device for high voltage applications is provided, the method comprising providing a substrate, embedding a die having a first and a second surface in the substrate, arranging a first heatsink at a first surface of the substrate, and arranging a second heatsink at a second surface of the substrate, wherein the embedding comprises arranging a thermally conductive structure between the first surface of the die and the first heatsink, and arranging a thermally isolating structure between the second surface of the die and the second surface of the substrate opposite the first surface.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a semiconductor device according to the first aspect of the present disclosure.

FIG. 2 illustrates a schematic top-side view of the semiconductor device of FIG. 1.

FIG. 3 illustrates an embodiment of the semiconductor device of FIG. 1.

FIG. 4 is a further cross-sectional illustration of the semiconductor device of the first aspect of the disclosure.

FIGS. 5a and 5b are schematic cross-sectional views of a layer structure of an embedding substrate according to the first aspect of the disclosure.

FIG. 6 is a flow-diagram of the second aspect of the disclosure.

FIG. 7 is a further flow-diagram of the second aspect of the disclosure.

### DETAILED DESCRIPTION

In the following, the above figures are described by way of examples.

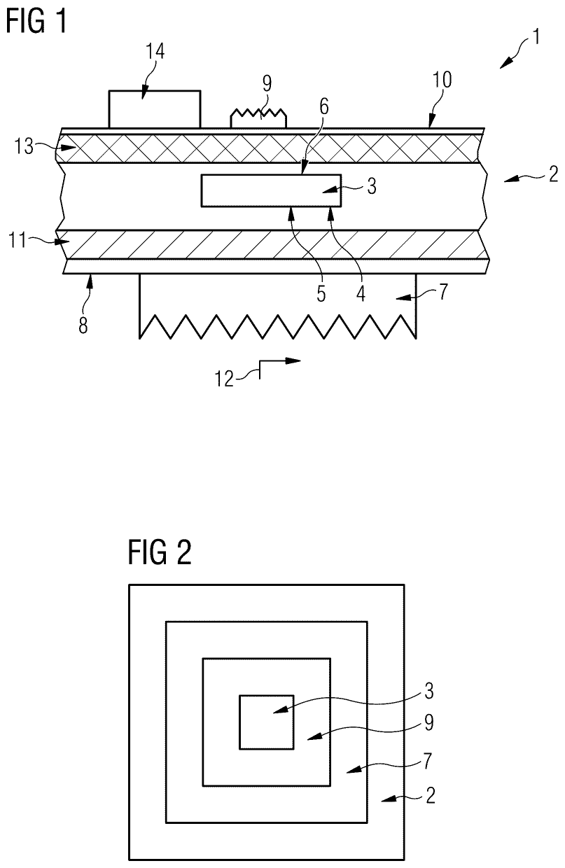

FIG. 1 illustrates a semiconductor device 1 according to the first aspect of the present disclosure. The semiconductor device 1 comprises a substrate 2. A semiconductor die 3 is embedded in the substrate 2. The substrate 2 fully surrounds the die 3, wherein the die 3 is arranged in a cavity 4 inside the substrate 2. The substrate 2 is a PCB and comprises multiple layers, as will be detailed below.

The die 3 comprises a first lower surface 5, and a second, upper surface 6. A first heatsink 7 is arranged at a first, lower surface 8 of the substrate 2. Opposite the first heatsink 7, a second heatsink 9 is arranged on a top side, second surface 10 of the substrate 2.

The substrate 2 is a multilayer substrate and comprises a thermally conductive structure 11. The thermally conductive structure 11 is a layer structure and is located between the die 3 and the first lower surface 8 of the substrate 2. The thermally conductive structure 11 can also be a continuous monolithic structure. Hence, the thermally conductive layer 11 transfers heat from the die 3, which is a heat source during operation, to the first heatsink 7, where the heat is to be dissipated and lead away from the semiconductor device 1, e.g. to the surrounding air or any other cooling medium 12. Further, a thermally isolating structure 13, which can also be a layer structure and/or a layered structure and/or continuous monolithic structure, is arranged between the die 3, i.e. the second surface of the die 6, and the top-side surface of the substrate 10. Transfer of heat emerging from the die 3 to the top-side of the substrate is hampered, resulting in a reduced heat flux to the top side of the substrate and hence lower temperatures on the top-side 10 of the substrate 2. Additional devices 14 (SMDs) are mounted on the top-side surface 10 of the substrate 2.

FIG. 2 illustrates a schematic top-side view of the semiconductor device 1 described in FIG. 1. Heat emitted by the operating die 3 is transferred to either side of the substrate 8, 10 and spread by both the thermally isolating structure 13 and the thermally conductive structure 11 and all additional layers of the multiple layer substrate between the die 3 and the lower and upper surface 8, 10 of the substrate 2. To efficiently transfer heat from the surfaces 8, 10 of the substrate to the surrounding cooling medium 12, the first heatsink 7 is mounted on the lower side of the substrate 2, wherein a footprint of the substrate 2 may be bigger than the footprint of the first heatsink 7. A footprint of the first heatsink 7 overlaps the footprint of the die 3, i.e. the die 3 is located inside the footprint of the first heatsink 7 from a top-side perspective. The second heatsink 9 has a footprint that is bigger than the footprint of the die 3, i.e. the die 3 is located inside the footprint of the second heatsink 9 from a top-side perspective. In another embodiment the footprint of the second heatsink 9 is smaller than the footprint of the die 3, i.e. the second heatsink 9 can be located inside the footprint of the die 3. Heat reaching the first and/or second heatsink 7, 9 through the substrate 2 from the die 3 which has generally a smaller footprint is hence better received and lead away from the substrate 2.

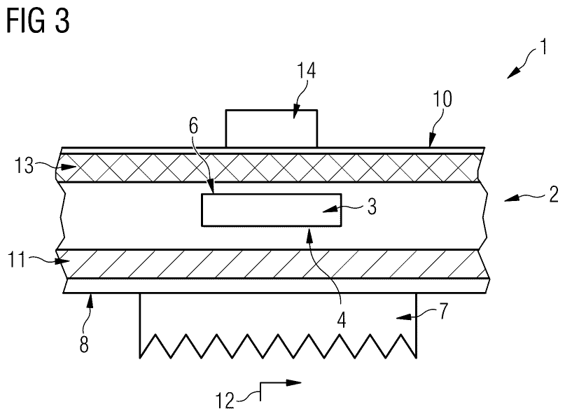

FIG. 3 illustrates an embodiment of the semiconductor device 1 of FIG. 1. in place of the second heatsink 9 a SMD 14 is placed in an area overhead the die 3 on the top-side surface of the substrate 2. Heat emerging from the die 3 dissipates inside the substrate 2 and reaches the topside of the substrate 2 over time. Consequently, the topside surface of the substrate 2 heats up and heat must be transferred to the surrounding medium 12 to stop the topside heating up. Therefore, a non-heat-sensitive SMD 14 is placed overhead the die to serve as a second heatsink 9. The SMD increases the surface overhead the die 3 which is in contact with the surrounding medium 12. The SMD 14 thus serves as a heat exchanger. The SMD 14 is arranged inside a footprint of the die 3, i.e. a lateral surface dimension of the die 3 may be bigger than a lateral surface dimension of the SMD. A lateral dimension of the second heatsink 9/SMD may however be smaller than a lateral dimension of the die 3.

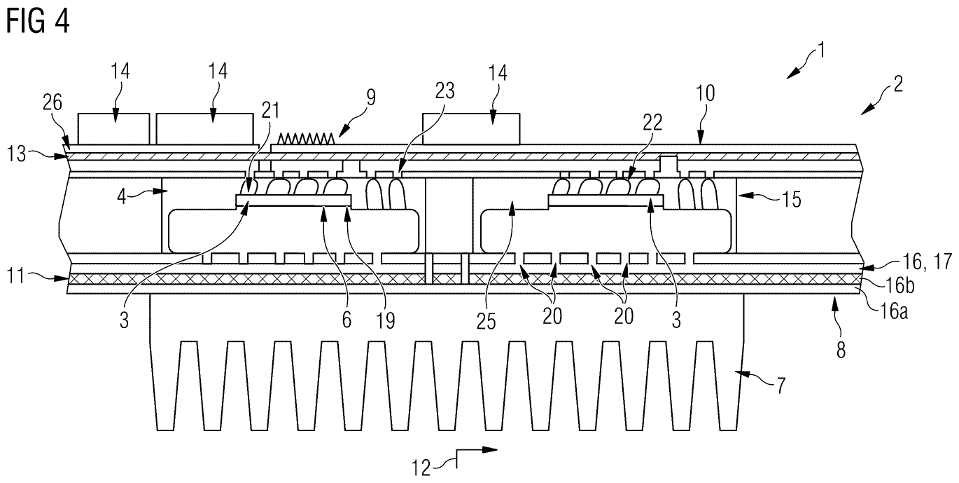

FIG. 4 is a further cross-sectional illustration of the semiconductor device 1 of the first aspect of the disclosure. FIG. 4 shows a layered substrate 2, which is a PCB, having two recesses 15. The recesses 15 form the cavity 4 which houses the die 3. The substrate further comprises a leadframe 16.

In the present example, the first heatsink 7 is attached to the first side of the substrate 8, which is coated with a first metal layer 16a. The first metal layer 16 a may be a copper layer and/or a galvanic copper layer having a thickness between 70 μm and 140 μm. The first metal layer 16a is followed by an epoxy layer 16b having a thickness of about 140 μm. The epoxy layer 16b is of an enhanced thermal conductivity epoxy or a PP and may form the thermally isolating structure 11 or be a part of it. A second metal layer 17 is deposited on the epoxy layer 16b.

The thermally conductive structure 11 may comprise the epoxy layer 16b and the second metal layer 17 disposed between the first heatsink 7 and the lower, first surface 5 of the die 3. The leadframe 16 may be of copper or of galvanic copper, wherein the epoxy layer can be a pre-impregnated thermoplastic or thermosetting matrix (PP). The PP may contain mostly flat textile semi-finished products such as unidirectional layers of threads or fabrics or scrims with threads arranged at right angles.

The leadframe 16 comprises a heat spreading portion 18, which is pillow-shaped. The heat spreading portion 18 is of copper or any other suitable material. The die 3 is attached to the heat spreading portion 18 by way of a thermally conductive adhesive layer 19, which fixedly adjoins the lower side of the die 3 to the heat spreading portion 18 of the leadframe 16. The heat spreading portion 18 comprises and is connected to the second metal layer 17 by a first via structure 20. The first via structure 20 connects the pillow-shaped heat spreading portion 18 thermally and electrically to the second metal layer 17. The first via structure 20 may also be part of the thermally conductive structure 11, as the vias 20 may act as heat conductors.

The leadframe 16 is disposed on or is part of the thermally conductive structure 11, enabling heat to be efficiently transferred from the die 3 via the heat spreading portion 18 through the first via structure 20 towards the thermally conductive structure 11 (in this example an epoxy layer) and hence towards the first heatsink 7.

On the upper, first surface 5 of the die 3, layer-shaped electrical contact pads 21 are disposed. Wire bonds 22 are disposed at the contact pads 21, connecting the die 3 via the contact pads 21 to a second via structure 23. The second via structure 23 is connected to an upper layer structure 24. The upper layer structure 24 forms a wiring layer electrically connecting the several dies 3 in the shown parallel cavities 4. The cavities 4 are filled with a mold compound 25.

The upper layer structure 24 is part of the multilayer substrate 2 and disposed between the first upper surface 5 of the die 3 and the topside 10 of the substrate 2. The thermally isolating structure 13 is disposed between the upper layer structure 24 and the topside 10 of the substrate 2. The thermally isolating structure 13 is partially covered by a cover layer 26, which is a second metal layer. The thermally isolating structure 13 thermally and electrically isolates the upper layer structure from the cover layer 26 and the topside surface 10 of the substrate 2. The second heatsink 9 is arranged overhead the die 3 at the cover layer 26 and thermally connected to the cover layer 26. By virtue of the second heatsink 9, surface temperatures of 65-90° Celsius can be realized at the area overhead the die 3, while a temperature directly at the die 3 (junction temperature) is about 150° Celsius during operation. A temperature of the first heatsink may be around 80-90° C. during operation.

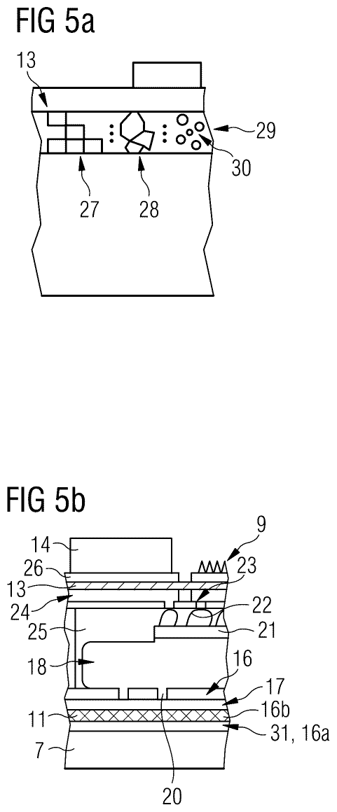

FIGS. 5a and 5b are schematic cross-sectional views of a layer structure of an embedding multilayer substrate 2 according to the first aspect of the disclosure.

FIG. 5a is a schematic view focusing on several embodiments of the thermally isolating structure 13. The different embodiments are depicted in the same FIG. 5a. However, the different embodiments are compatible amongst one another and can be implemented at the discretion of a person skilled in the art. The thermally isolating structure 13 is a brick structure 27 being formed of a plurality of brick-shaped isolating elements. Generally, the thermally isolating structure 13 may comprise several independent isolating elements or the thermally isolating structure may consist of a combination of the embodiments described herein.

Further, the thermally isolating structure 13 may be a honeycomb structure 28. The cavities of the honeycomb structure 28 may be filled with an isolation compound or with any suitable isolating gas. The thermally isolating structure 13 may also be a structure comprising gas-filled cavities 29. The gas filled cavities are embedded in a matrix 30 consisting of any suitable thermally isolating material.

FIG. 5b is s schematic cross-sectional view of a layer structure of an embedding multilayer substrate 2. An interposer layer 31 is disposed between the first heatsink 7 and the thermally conductive structure 13. The interposer layer 31 forms the lower surface 8 of the substrate 2 and may be equal to the first metal layer 16a. The second metal layer 17 is arranged on a top side of the thermally conductive structure 13 between the thermally conductive structure 13 and the epoxy layer 16b. Epoxy layer 16b is arranged between the second metal layer 17 and a further epoxy layer (not shown) and/or the heat spreading portion 18. The further epoxy layer may form the core of the substrate and may have a thickness of about 1270 μm. The thickness of the further epoxy layer is about the vertical dimension of the cavity 4. The heat spreading portion 18 is encapsuled by mold compound 25 forming a mold layer. Mold compound 25 fills the cavity 4 and encapsulates at least the second surface of the die 6. Wire bonds 22 are connected to respective bond pads 21 at the second surface of the die 6 and connect the control side of the die 3 to the second via structure 23. The upper layer structure 24 is arranged atop the mold compound 25 and arranged between the mold compound 25 and the thermally isolating structure 13. The thermally isolating structure 13 has a thickness of about 140 μm and is a continuous structure. Particularly, the thermally isolating structure 13 has no through connections from the second via structure 23 upper layer structure 24 or a cover layer 26. The upper layer structure 26 is a metal layer forming a wiring layer. The upper layer structure 26 may be electrically connected to the cover layer 26 by a third via structure (not shown). The thermally isolating structure 13 is covered by the electrically conductive cover layer 26, which forms the second surface 10 of the substrate 2. SMDs 14 and/or second heatsink 9 is/are arranged at the top surface 10 of the substrate 2.

During operation of the die 3, a junction temperature, a temperature at the hottest point of the die 3 will be about 150° C. Subsequently, a temperature of the core material of the substrate 2 in the close vicinity (adjacent the cavity 4) of the mold compound 25, e.g. of the further epoxy layer will be in a range from 120° C.-130° C. A temperature of the core material of the substrate 2 in a wider vicinity of the cavity 4 will be in a range of about 60° C.-80° C. As heat will be distributed by the heat spreading portion 18 and will be lead away from the die 3 towards the thermally conductive structure 11 via the first via structure 20 and the second metal layer 17, a temperature of the first via structure 20 and of the second metal layer 17 will be in a range from 135° C.-145° C. The first heatsink 7 will have a temperature in a range of 80° C.-90° C. In turn, by virtue of the thermally isolating structure 13, a temperature at the cover layer 26 and/or the second heatsink 9 can be reduced from a range of 130° C.-140° C. down to 65° C.-95° C. Particularly, this effect can be achieved by implementing a continuous thermally isolating structure 13 and by omitting any thermally and/or electrically conductive through connections inside the footprint of the die. Electrical connections, i.e. the third via structure for electrically connecting the upper layer structure 24 with the cover layer 26 are to be spaced apart from the die 3 in a lateral dimension of the substrate 2.

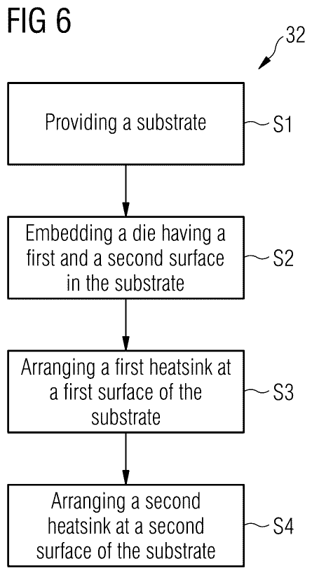

FIG. 6 is a flow-diagram of the second aspect of the disclosure. According to the method 32 for manufacturing the semiconductor device 1 of the first aspect of the disclosure, in step S1 a substrate 2 is provided. In step S2 a die 3 having a first 5 and a second 6 surface opposite the first surface 5 is embedded into the substrate 2. In step S3 a first heatsink 7 is arranged at a first surface 8 of the substrate 2. In step S4 a second heatsink 9 is arranged at a second surface 10 of the substrate 2.

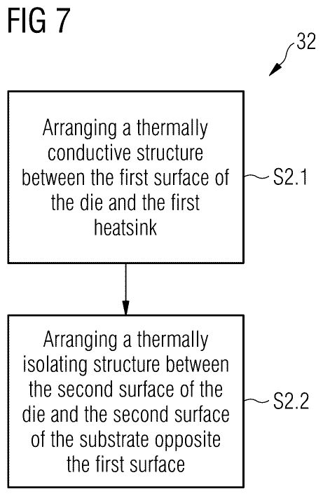

FIG. 7 is a further flow-diagram of the second aspect of the disclosure. The steps of FIG. 7 further specify step S2 of FIG. 6.

Embedding a die 3 into the substrate 2 of step S2 further comprises steps S2.1 and S2.2. In step S2.1 the embedding comprises arranging a thermally conductive structure 11 between the first surface 5 of the die 3 and the first heatsink 7. Further, according to step S2.2 a thermally isolating structure 13 is arranged between the second surface 6 of the die 3 and the second surface 10 of the substrate 2, which is opposite the first surface 8 of the substrate 2.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

### LIST OF REFERENCE SIGNS

1 semiconductor device
2 substrate
3 die
4 cavity
5 first surface of the die
6 second surface of the die
7 first heatsink
8 first lower surface of substrate
9 second heatsink
10 topside/second surface of the substrate
11 thermally conductive structure
12 surrounding air/cooling medium
13 thermally isolating structure
14 SMD
15 recess
16 leadframe
16a first metal layer
16b epoxy layer
17 second metal layer
18 heat spreading portion
19 adhesive layer
20 first via structure
21 contact pads
22 wire bonds
23 second via structure
24 upper layer structure
25 mold compound
26 cover layer
27 brick structure
28 honeycomb structure
29 gas-filled cavities
30 matrix
31 interposer layer
32 method for manufacturing a semiconductor device

What is claimed is:

1. A semiconductor device, comprising:
a substrate;
a die having a first and a second surface, wherein the die is embedded in the substrate;
a first heatsink arranged at a first surface of the substrate;
a second heatsink arranged at a second surface of the substrate opposite the first surface;
wherein the substrate comprises:
a thermally conductive structure arranged between the first surface of the die and the first heatsink; and
a thermally isolating structure arranged between the second surface of the die and the second surface of the substrate.

2. The semiconductor device of claim 1, wherein a footprint of the first heatsink overlaps a footprint of the die.

3. The semiconductor device of claim 1, wherein a footprint of the second heatsink overlaps a footprint of the die.

4. The semiconductor device of claim 1, wherein the second heatsink is a device mounted on the second surface of the substrate.

5. The semiconductor device of claim 1, wherein the substrate comprises a leadframe, wherein the leadframe comprises a heat spreading portion configured to contact the first side of the die, the heat spreading portion comprising a via structure to contact a metal layer arranged between the heat spreading portion and the first side of the substrate, and wherein the metal layer is part of the thermally conductive structure.

6. The semiconductor device of claim 1, wherein the thermally isolating structure has a heat transfer coefficient below 0.3 W/mK.

7. The semiconductor device of claim 6, wherein the thermally isolating structure is one of a honeycomb structure, a brick structure, a gas filled honeycomb structure, and a structure comprising gas-filled cavities.

8. The semiconductor device of claim 1, wherein the thermally isolating structure is a continuous structure above the die and is free of through-connections.

9. The semiconductor device of claim 1, further comprising a plurality of electrical through-connections connecting a wiring layer contacting the die and a metallic cover layer on the surface of the substrate, wherein the electrical through-connections are arranged outside a footprint of the die and/or outside a footprint of the second heatsink.

10. A method for manufacturing a semiconductor device for high voltage applications, the method comprising:
providing a substrate;
embedding a die having a first and a second surface in the substrate;
arranging a first heatsink at a first surface of the substrate; and
arranging a second heatsink at a second surface of the substrate opposite the first surface;
wherein the embedding comprises:
arranging a thermally conductive structure between the first surface of the die and the first heatsink; and
arranging a thermally isolating structure between the second surface of the die and the second surface of the substrate.
